(19) United States
(12) Patent Application Publication
(10) Pub. No.: US 2024/0364291 A1
(43) Pub. Date: Oct. 31, 2024

(54) CIRCUIT BOARD AND CONNECTOR DEVICE HAVING THE SAME

(71) Applicant: TDK Corporation, Tokyo (JP)

(72) Inventors: Toshiyuki ABE, Tokyo (JP); Ichiro YAGINUMA, Tokyo (JP); Kazutoshi TSUYUTANI, Tokyo (JP); Takuya SHIMAMURA, Tokyo (JP)

(21) Appl. No.: 18/641,783

(22) Filed: Apr. 22, 2024

Related U.S. Application Data
(60) Provisional application No. 63/498,094, filed on Apr. 25, 2023.

(51) Int. Cl. H03H 7/01; H01R 12/58; H01R 12/75; H01R 13/66; H01R 13/7197; H05K 1/11; H05K 1/16; H05K 1/18

(52) U.S. Cl. CPC H03H 7/01; H01R 13/7197; H05K 1/117; H05K 1/165; H05K 1/185; H01R 12/58; H01R 12/75; H01R 13/6666; H05K 2201/09181; H05K 2201/10174; H05K 2201/10189

(57) ABSTRACT

Disclosed herein is a circuit board that includes: a plurality of insulating layers, a common mode filter and an electronic component embedded in the insulating layers, and first to fifth outer electrodes. The first coil pattern of the common mode filter is connected between the first and second outer electrodes. The second coil pattern of the common mode filter is connected between the third and fourth outer electrodes. The electronic component is connected between the first and second outer electrodes and the fifth outer electrode. The electronic component is arranged so as not to overlap the first coil pattern and the second coil pattern.

### BACKGROUND OF THE ART

The present disclosure relates to a circuit board and a connector device having the circuit board.

The differential signal lines may undergo propagation of common mode noise or ESD (Electro-Static Discharge). The common node noise is usually removed using a common mode filter mounted on the substrate. The ESD is usually removed using an ESD protective element incorporated in IC chip.

### SUMMARY

One of the objectives of the present disclosure is to provide a circuit board that can remove the common mode noise and that can be housed in a receptacle.

A circuit board according to one aspect of the present disclosure a core insulating layer including a first main surface and a second main surface opposite to each other; an electronic component embedded in the core insulating layer and including a first inner electrode, a second inner electrode, and a third inner electrode; a first interlayer insulating layer and a second interlayer insulating layer stacked on the first main surface of the core insulating layer; a third interlayer insulating layer stacked on the second main surface of the core insulating layer and including a core material formed by a resin impregnated material; a first outer electrode, a second outer electrode, a third outer electrode, a fourth outer electrode, and a fifth outer electrode; a first coil pattern embedded in the first interlayer insulating layer and including a first end and a second end, the first end being electrically connected to the first outer electrode and the first inner electrode, and the second end being electrically connected to the second outer electrode; and a second coil pattern embedded in the second interlayer insulating layer so as to substantially overlap the first coil pattern and including a third end and a fourth end, the third end being electrically connected to the third outer electrode and the second inner electrode, and the fourth end being electrically connected to the fourth outer electrode. The third inner electrode is connected to the fifth outer electrode. The electronic component is arranged so as not to overlap the first coil pattern and the second coil pattern.

### BRIEF DESCRIPTION OF THE DRAWINGS

The above features and advantages of the present disclosure will be more apparent from the following description of certain embodiments taken in conjunction with the accompanying drawings, in which:

FIG. 1 is a schematic cross-sectional view for explaining the structure of a connector device 10 according to an embodiment of the present disclosure;

FIG. 2 is a front view of the receptacle 11 of an HDMI type E;

FIGS. 3A to 3C are respectively a perspective view, a side view, and a top view of a connector device 10A according to a first embodiment;

FIGS. 4A and 4B are respectively a transparent perspective view and a top view of the circuit board 50;

FIG. 5 is a schematic cross-sectional view for explaining the structure of the circuit board 50;

FIGS. 6A to 6E are schematic plan views respectively illustrating the structures of the conductor layers L1 to L5 and each show a portion corresponding to the unit circuit U0;

FIG. 7 is an equivalent circuit diagram of the unit circuit U0;

FIGS. 8A to 8D are respectively a perspective view, a side view, a top view, and a back view of a connector device 10B according to a second embodiment;

FIGS. 9A and 9B are respectively a transparent perspective view and a top view of the circuit board 150;

FIG. 10 is a schematic cross-sectional view for explaining the structure of the circuit board 150;

FIGS. 11A to 11E are schematic plan views respectively illustrating the structures of the conductor layers L1 to L5 and each show a portion corresponding to the unit circuit U0; and

FIG. 12 is a schematic cross-sectional view for explaining the structure of the circuit board embedded therein the chip type common mode filter.

### DETAILED DESCRIPTION OF THE EMBODIMENTS

Some embodiments of the present disclosure will be explained below in detail with reference to the accompanying drawings.

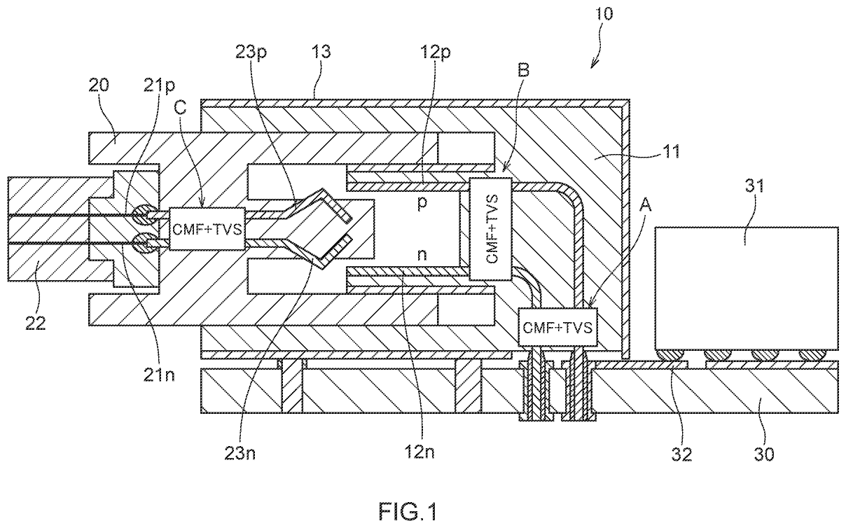

FIG. 1 is a schematic cross-sectional view for explaining the structure of a connector device 10 according to an embodiment of the present disclosure. The connector device 10 illustrated in FIG. 1 has a receptacle 11 and connector pins 12p and 12n provided in the receptacle 11. The periphery of the receptacle 11 may be covered with a shield 13 made of metal.

FIG. 1 illustrates a state where a connector plug 20 is inserted into the receptacle 11. The connector plug 20 is provided at the leading end of a cable 22 having a pair of differential signal lines 21p and 21n. The differential signal lines 21p and 21n are connected at their ends to connector pins 23p and 23n in the connector plug 20, respectively. When the connector plug 20 is correctly inserted into the receptacle 11, the connector pins 23p and 23n contact the connector pins 12p and 12n respectively, thereby establishing electrical connection therebetween.

The thus configured connector device 10 may be mounted on a substrate 30 through a solder or the like. The substrate 30 mounts thereon an IC 31. In the example illustrated in FIG. 1, the connector pin 12p is connected to the IC 31 through a wiring 32 provided in the substrate 30.

The differential signal lines 21p and 21n may undergo propagation of common mode noise or ESD (Electro-Static Discharge). The common node noise is usually removed using a common mode filter mounted on the substrate 30. The ESD is usually removed using an ESD protective element incorporated in IC 31. However, when the connector device 10 itself has the function of the common mode filter (CMF) or ESD protective element (e.g., TVS (Transient Voltage Suppressor)), a reduction in the number of components to be mounted on the substrate 30 and improvement in signal quality are expected. The CMF and TVS can be inserted at a position (reference symbol A) inside the connector device 10 and in the vicinity of the substrate 30 or at a position (reference symbol B) inside the connector device 10 and in the vicinity of the connector pins 12p and 12n. Alternatively, as denoted by reference symbol C, the CMF and TVS can be inserted inside the connector plug 20. To address a risk of ESD at connector insertion and extraction, the CMF and TVS may be disposed at both the positions A and B. Examples of the ESD protective element may include a Varistor and an Arrester, in addition to the TVS.

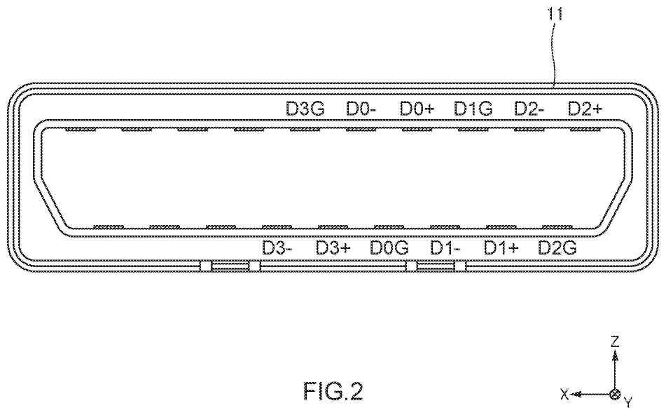

FIG. 2 is a front view of the receptacle 11 of an HDMI type E. The receptacle 11 illustrated in FIG. 2 has an opening constituting the XZ plane. The connector plug 20 is inserted into the opening of the receptacle 11 in the Y-direction. The inner wall of the receptacle 11 has a pair of differential signal terminals D0− and D0+ and their corresponding ground terminal D0G, a pair of differential signal terminals D1− and D1+ and their corresponding ground terminal D1G, a pair of differential signal terminals D2− and D2+ and their corresponding ground terminal D2G, and a pair of differential signal terminals D3− and D3+ and their corresponding ground terminal D3G. Thus, when the connector plug 20 is inserted into the receptacle 11, four pairs of differential signals are transmitted/received in parallel. The terminals D2+, D2−, D1G, D0+, D0−, and D3G are arranged in this order in the X-direction on the upper inner wall of the receptacle 11, and the terminals D2G, D1+, D1−, D0G, D3+, and D3− are arranged in this order in the X-direction on the lower inner wall of the receptacle 11.

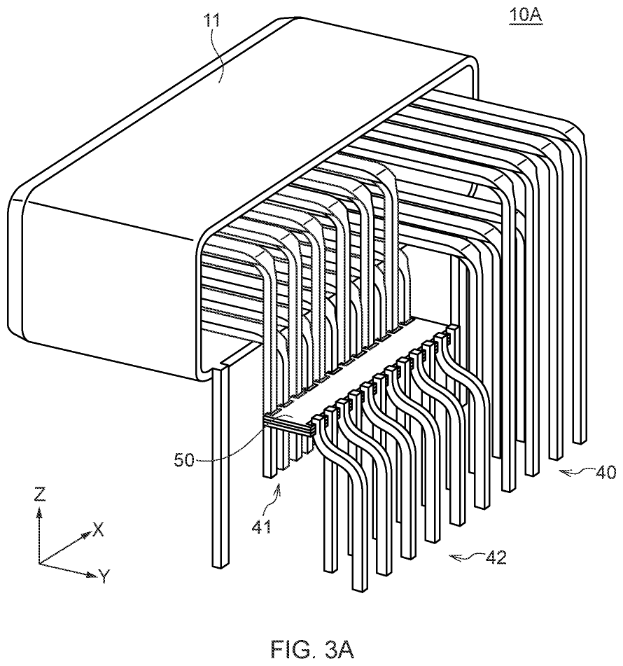

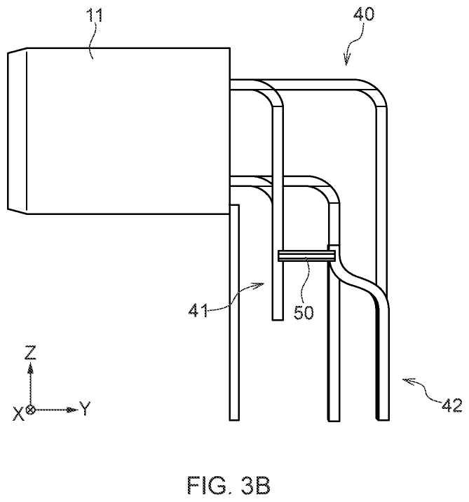

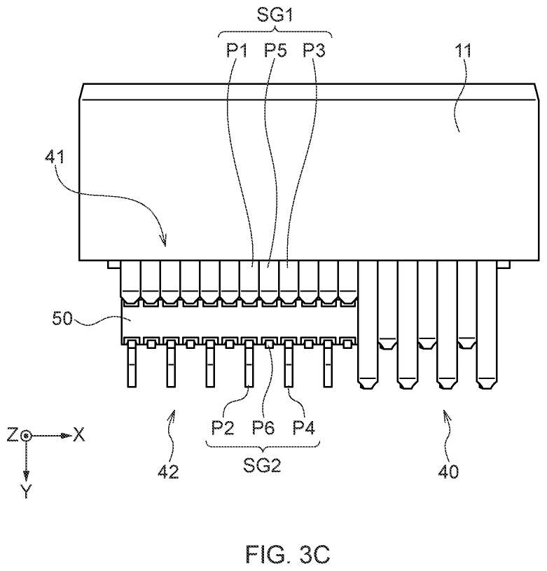

FIGS. 3A to 3C are respectively a perspective view, a side view, and a top view of a connector device 10A according to a first embodiment. As illustrated in FIGS. 3A to 3C, the connector device 10A according to the first embodiment has a plurality of input lead terminals 41 connected to respective terminals provided in the receptacle 11. The plurality of input lead terminals 41 extend in the Y-direction from the receptacle 11 and bent in the Z-direction. The plurality of input lead terminals 41 bent in the Z-direction are arranged in a line in the X-direction such that those corresponding to the terminals provided on the upper inner wall of the receptacle 11 and those corresponding to the terminals provided on the lower inner wall of the receptacle 11 are alternately arranged. As a result, the plurality of input lead terminals 41 bent in the Z-direction are arranged in the X-direction in the order of D2+, D2G, D2−, D1+, D1G, D1−, D0+, D0G, D0−, D3+, D3G, and D3−. The connector device 10A has a plurality of output lead terminals 42 corresponding to the above input lead terminals 41. The plurality of output lead terminals 42 extend in the Z-direction.

The plurality of input and output lead terminals 41 and 42 are respectively connected to each other through a circuit board 50. The circuit board 50 has a plate-like shape whose longer-side direction is parallel to the X-direction, whose shorter-side direction is to the Y-direction, and whose thickness direction is to the Z-direction. The circuit board 50 is disposed inside the connector device 10A so as to be sandwiched in the Y-direction between the plurality of input and output lead terminals 41 and 42. The plurality of input and output lead terminals 41 and 42 have elasticity biasing the circuit board 50. Thus, the plurality of input and output lead terminals 41 and 42 directly contact each other not through a solder or the like. A plurality of lead terminals 40 illustrated in FIGS. 3A to 3C do not constitute the differential signal lines.

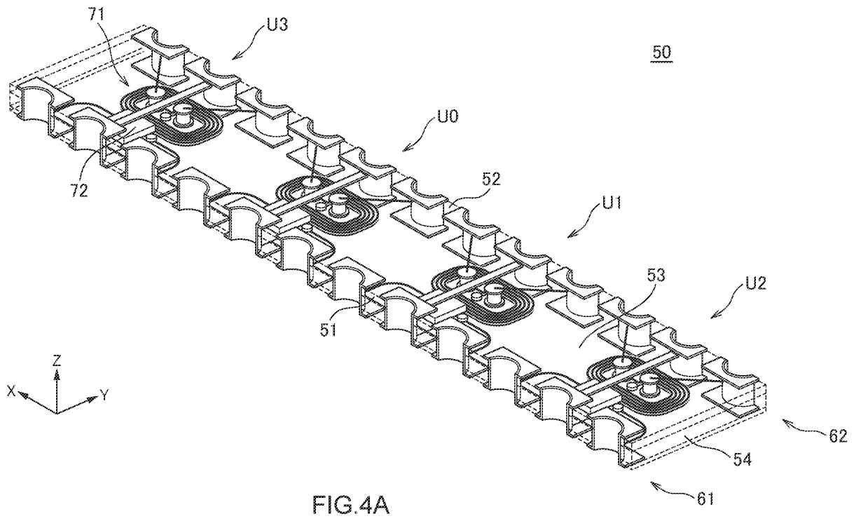

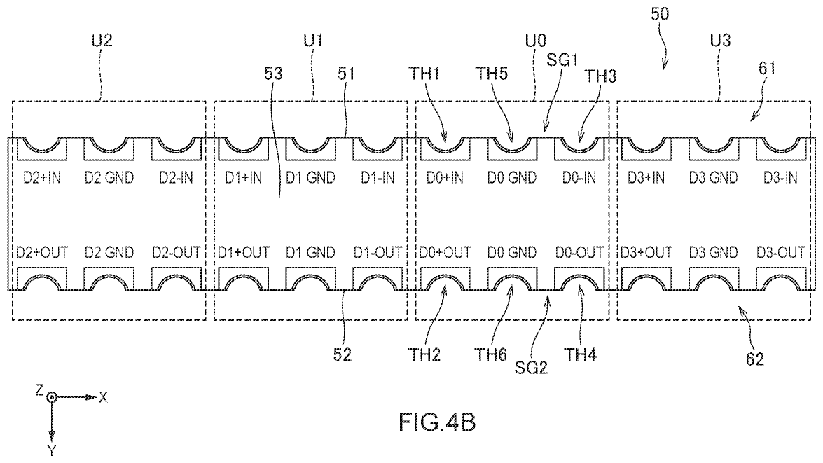

FIGS. 4A and 4B are respectively a transparent perspective view and a top view of the circuit board 50. As illustrated in FIGS. 4A and 4B, the circuit board 50 has side surfaces 51 and 52 positioned on the mutually opposite sides and constituting the XZ plane. The circuit board 50 has a plurality of external electrodes including a plurality of input terminals 61 and a plurality of output terminals 62. The plurality of input terminals 61 are arranged in the X-direction along the side surface 51. The plurality of output terminals 62 are arranged in the X-direction along the side surface 52. The plurality of input terminals 61 include input terminals D2+IN, D2GND, D2−IN, D1+IN, D1GND, D1−IN, D0+IN, D0GND, D0−IN, D3+IN, D3GND, and D3−IN which are arranged in the X-direction. The plurality of output terminals 62 include output terminals D2+OUT, D2GND, D2−OUT, D1+OUT, D1GND, D1−OUT, D0+OUT, D0GND, D0−OUT, D3+OUT, D3GND, and D3−OUT which are arranged in the X-direction.

The above input and output terminals 61 and 62 are each provided on the inner wall of a through hole exposed to the side surfaces 51 and 52 of the circuit board 50 and further on the upper and lower surfaces 53 and 54 positioned on the mutually opposite sides and constituting the XY plane. For example, the input terminal D0+IN is provided on the inner wall of a through hole TH1, the input terminal D0+OUT is provided on the inner wall of a through hole TH2, the input terminal D0−IN is provided on the inner wall of a through hole TH3, and the input terminal D0−OUT is provided on the inner wall of a through hole TH4. A through hole TH5 is positioned between the through holes TH1 and TH3, and the ground terminal D0GND included in the input terminals 61 is provided on the inner wall thereof. Further, a through hole TH6 is positioned between the through holes TH2 and TH4, and the ground terminal D0GND included in the output terminals 62 is provided on the inner wall thereof.

The through holes exposed to the side surfaces 51 and 52 each have a semi-circular shape as viewed in the Z-direction. The plurality of input lead terminals 41 are each disposed in the semicircular through hole provided in the side surface 51 so as to bias the side surface 51. The plurality of output lead terminals 42 are each disposed in the semicircular through hole provided in the side surface 52 so as to bias the side surface 52. For example, lead terminals P1, P3, and P5 (FIG. 3C) of the plurality of input lead terminals 41 respectively contact the input terminals D0+IN, D0−IN, and D0GND provided on the inner walls of the respective through holes TH1, TH3, and TH5 illustrated in FIG. 4B. Lead terminals P2, P4, and P6 (FIG. 3C) of the plurality of output lead terminals 42 respectively contact the output terminals D0+OUT, D0−OUT, and D0GND provided on the inner walls of the respective through holes TH2, TH4, and TH6 illustrated in FIG. 4B.

As illustrated in FIG. 4A, the circuit board 50 incorporates four common mode filters 71 and four TVS chips 72. The circuit board 50 is an array product including four mutually independent unit circuits U0 to U3, to each of which one common mode filter 71 and one TVS chip 72 are allocated. The above-mentioned lead terminals P1, P3, and P5 of the plurality of input lead terminals 41 constitute a sub-group SG1 allocated to the unit circuit U0. Similarly, the above-mentioned lead terminals P2, P4, and P6 of the plurality of output lead terminals 42 constitute a sub-group SG2 allocated to the unit circuit U0.

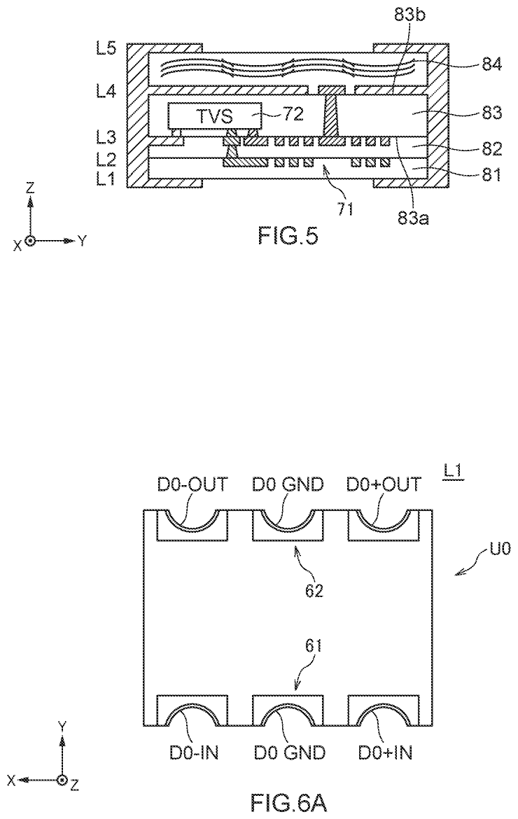

FIG. 5 is a schematic cross-sectional view for explaining the structure of the circuit board 50. As illustrated in FIG. 5, the circuit board 50 has a structure in which conductor layers L1 to L5 and interlayer insulating films 81 to 84 are alternately stacked. The interlayer insulating films 81 and 82 are made of a resin material not containing a core material such as glass cloth and have the conductor layers L2 and L3 respectively embedded therein. The conductor layers L2 and L3 partly constitute the common mode filter 71. The interlayer insulating film 83 is a core insulating layer and has the TVS chip 72 embedded therein. The interlayer insulating film 83 is also made of a resin material not containing a core material such as glass cloth. On the other hand, the interlayer insulating film 84 is a layer having high strength which is made of a material obtained by impregnating a core material such as glass cloth with a resin material. The thickness of the interlayer insulating film 84 may be larger than the total thickness of the interlayer insulating films 81 and 82. The interlayer insulating film 83 has main surfaces 83a and 83b constituting the XY plane and positioned on the mutually opposite sides. The interlayer insulating films 82 and 81 are stacked in this order on the main surface 83a of the interlayer insulating film 83, and the interlayer insulating film 84 is stacked on the main surface 83b of the interlayer insulating film 83.

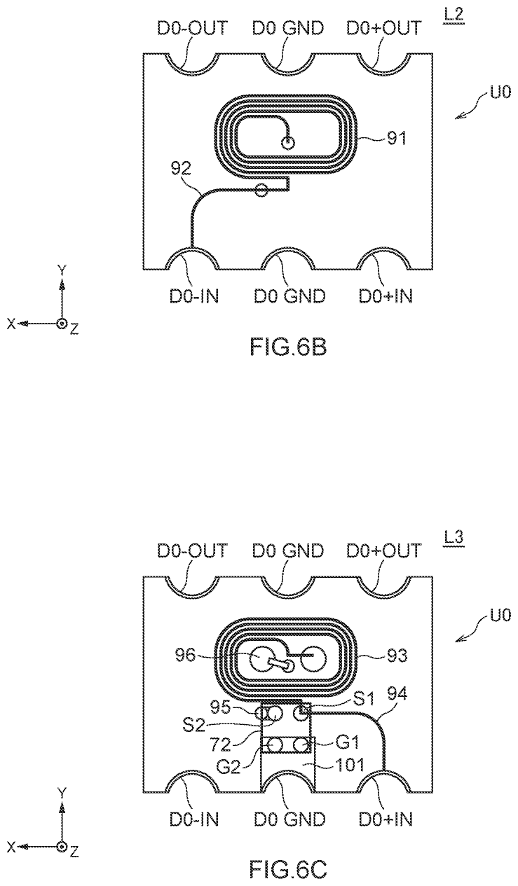

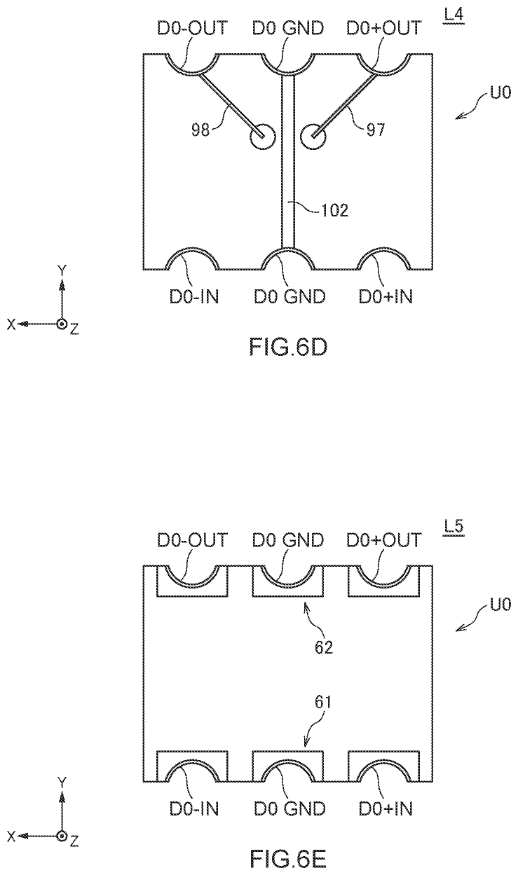

FIGS. 6A to 6E are schematic plan views respectively illustrating the structures of the conductor layers L1 to L5 and each show a portion corresponding to the unit circuit U0.

As illustrated in FIG. 6A, the conductor layer L1 includes a plurality of input terminals 61 and a plurality of output terminals 62. The plurality of input terminal 61 include the input terminals D0+IN, D0GND, and D0−IN which are arranged in the X-direction. The plurality of output terminals 62 include the output terminals D0+OUT, D0GND, and D0−OUT which are arranged in the x-direction. The input terminal D0+IN and output terminal D0+OUT are arranged in the Y-direction. The input terminal D0−IN and output terminal D0−OUT are arranged in the Y-direction. The ground terminal D0GND included in the input terminals 61 and the ground terminal D0GND included in the output terminals 62 are arranged in the Y-direction.

As illustrated in FIG. 6B, the conductor layer L2 includes a coil pattern 91 wound in a plurality of turns and a connection pattern 92 connecting the outer peripheral end of the coil pattern 91 and the input terminal D0−IN.

As illustrated in FIG. 6C, the conductor layer L3 includes a coil pattern 93 wound in a plurality of turns and a connection pattern 94 connecting the outer peripheral end of the coil pattern 93 and the input terminal D0+IN. The coil patterns 91 and 93 overlap each other in a plan view (as viewed in the Z-direction) to constitute the common mode filter 71 illustrated in FIG. 5.

In FIG. 6C, the TVS chip 72 embedded in the interlayer insulating film 83 is illustrated. The TVS chip 72 has signal terminals S1, S2 and ground terminals G1, G2 which are internal electrodes thereof. The TVS chip 72 is disposed so as not to overlap the coil patterns 91 and 93 in a plan view (as viewed in the Z-direction). This reduces interference between magnetic flux generated from the coil patterns 91, 93 and the TVS chip 72.

The conductor layer L3 further includes a connection pattern 95 provided outside the coil pattern 93. The connection pattern 95 is connected to the connection pattern 92 included in the conductor layer L2 through a via penetrating the interlayer insulating film 82. The connection pattern 94 is connected to the signal terminal S1 of the TVS chip 72. The connection pattern 95 is connected to the signal terminal S2 of the TVS chip 72. The ground terminals G1 and G2 of the TVS chip 72 are connected in common to the ground terminal D0GND through a ground pattern 101 included in the conductor layer L3. The conductor layer L3 further includes a connection pattern 96 provided in the inner diameter area of the coil pattern 93. The connection pattern 96 is connected to the inner peripheral end of the coil pattern 91 included in the conductor layer L2 through a via penetrating the interlayer insulating film 82.

As illustrated in FIG. 6D, the conductor layer L4 includes connection patterns 97 and 98 and a ground pattern 102. One end of the connection pattern 97 is connected to the output terminals D0+OUT, and the other end thereof is connected to the inner peripheral end of the coil pattern 93 included in the conductor layer L3 through a via penetrating the interlayer insulating film 83. One end of the connection pattern 98 is connected to the output terminal D0−OUT, and the other end thereof is connected to the connection pattern 96 included in the conductor layer L3 through a via penetrating the interlayer insulating film 83. The ground pattern 102 connects the ground terminal D0GND on the input terminal 61 side and the ground terminal D0GND on the output terminal 62 side.

As illustrated in FIG. 6E, the conductor patterns included in the conductor layer L5 are the same in shape and position as those of the conductor patterns included in the conductor layer L1.

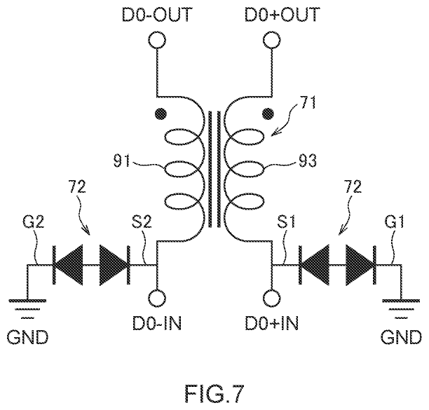

With the above configuration, the unit circuit U0 constitutes the circuit illustrated in FIG. 7. More specifically, the common mode filter 71 formed by the coil patterns 91 and 93 is connected between the pair of input terminals D0−IN and D0+IN and the pair of output terminals D0−OUT and D0+OUT, and the TVS chip 72 is connected between the pair of input terminals D0−IN and D0+IN and the ground terminal D0GND. The TVS chip 72 includes a protective diode connected between the signal terminal S1 and the ground terminal G1 and a protective diode connected between the signal terminal S2 and the ground terminal G2. Accordingly, one end of the coil pattern 91 is connected in common to the input terminal D0−IN and signal terminal S2, and one end of the coil pattern 93 is connected in common to the input terminal D0+IN and signal terminal S1. The ground terminals G1 and G2 of the TVS chip 72 are connected in common to the ground terminal D0GND.

Other unit circuits U1 to U3 have the same configuration as the unit circuit U0. Thus, the unit circuits U0 to U3 each can remove common mode noise to be superimposed on its corresponding differential signals and can remove ESD noise.

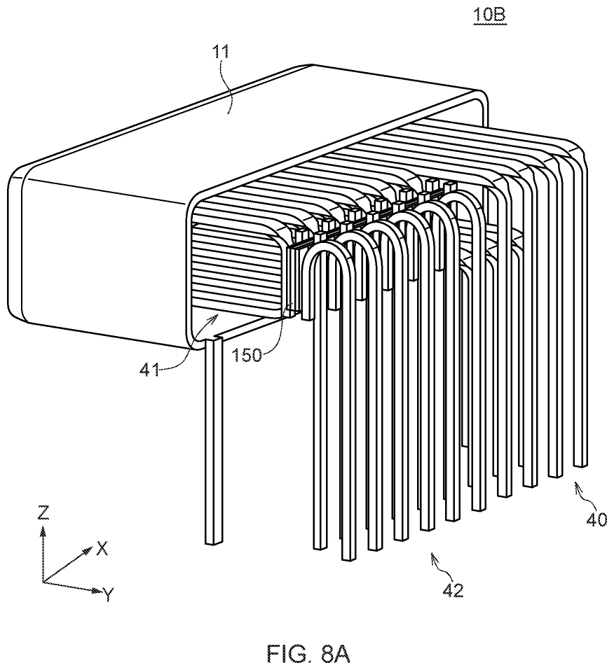

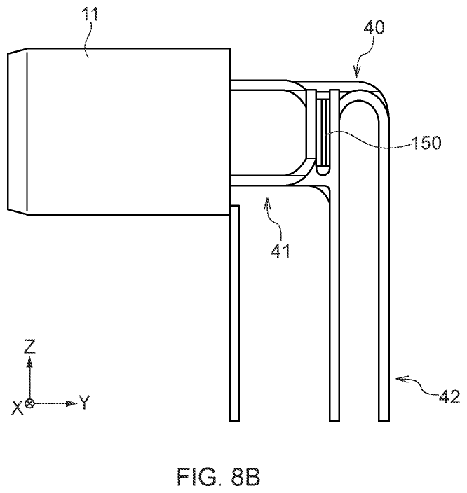

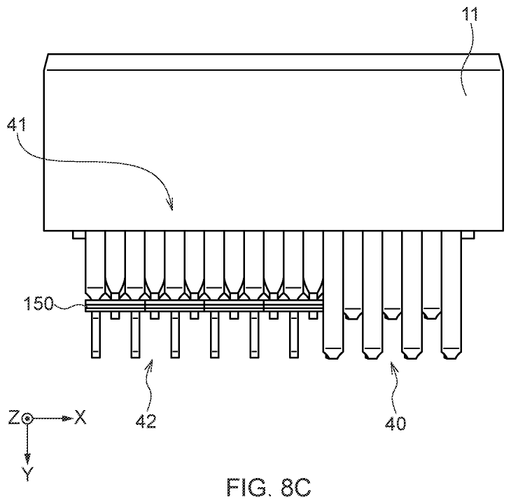

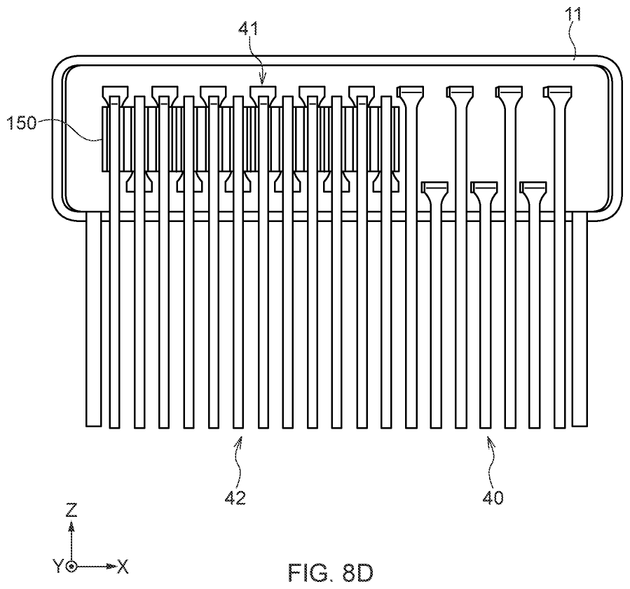

FIGS. 8A to 8D are respectively a perspective view, a side view, a top view, and a back view of a connector device 10B according to a second embodiment. As illustrated in FIGS. 8A to 8D, the connector device 10B according to the second embodiment has a plurality of input lead terminals 41 connected to respective terminals provided in the receptacle 11. The plurality of input lead terminals 41 extend in the Y-direction from the receptacle 11 and bent in the Z-direction. The plurality of input lead terminals 41 that are connected to terminals D2+, D2−, D1G, D0+, D0−, and D3G arranged along the upper inner wall of the receptacle 11 are bent in the negative Z-direction, and those that are connected to terminals D2G, D1+, D1−, D0G, D3+, and D3− arranged along the lower inner wall of the receptacle 11 are bent in the positive Z-direction. The plurality of input lead terminals 41 bent in the Z-direction are arranged in a line in the X-direction such that those corresponding to the terminal arranged along inner wall of the upper receptacle 11 and those corresponding to the terminal arranged along the lower inner wall of the receptacle 11 are alternately arranged. As a result, the plurality of input lead terminals 41 bent in the Z-direction are arranged in the X-direction in the order of D2+, D2G, D2−, D1+, D1G, D1−, D0+, D0G, D0−, D3+, D3G, and D3−. The connector device 10B has a plurality of output lead terminals 42 corresponding to the above input lead terminals 41. The plurality of output lead terminals 42 extend in the Z-direction.

The plurality of input and output lead terminals 41 and 42 are respectively connected to each other through a circuit board 150. The circuit board 150 has a plate-like shape whose longer-side direction is parallel to the X-direction, whose shorter-side direction is to the Z-direction, and whose thickness direction is to the Y-direction. The circuit board 150 is disposed inside the connector device 10B so as to be sandwiched in the Y-direction between the plurality of input and output lead terminals 41 and 42. The plurality of input and output lead terminals 41 and 42 have elasticity biasing the circuit board 150. Thus, the plurality of input and output lead terminals 41 and 42 directly contact each other not through a solder or the like.

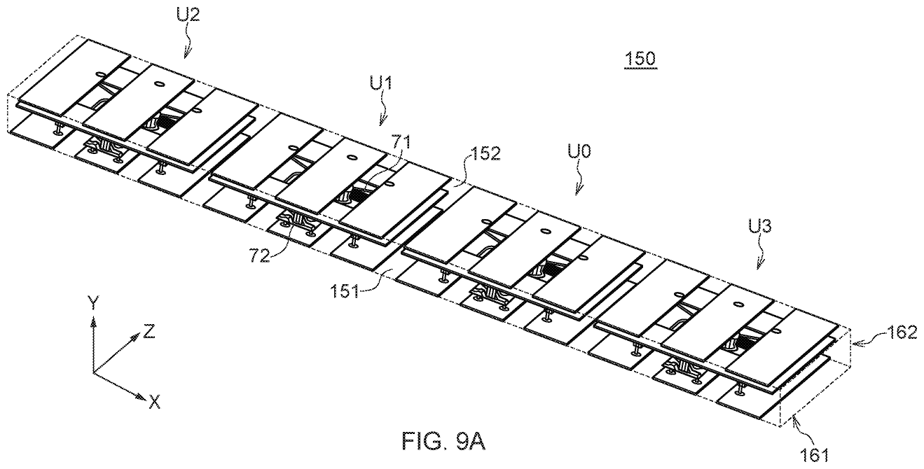

FIGS. 9A and 9B are respectively a transparent perspective view and a top view of the circuit board 150. As illustrated in FIGS. 9A and 9B, the circuit board 150 has an upper surface 151 and a lower surface 152 which are positioned on the mutually opposite sides and constitute the XY plane. The circuit board 50 has a plurality of input terminals 161 arranged in the X-direction on the upper surface 151 and a plurality of output terminals 162 arranged in the X-direction on the lower surface 152. The plurality of input terminals 161 include input terminals D2+IN, D2GND, D2−IN, D1+IN, D1GND, D1−IN, D0+IN, D0GND, D0−IN, D3+IN, D3GND, and D3−IN which are arranged in the X-direction. The plurality of output terminals 162 include output terminals D2+OUT, D2GND, D2−OUT, D1+OUT, D1GND, D1−OUT, D0+OUT, D0GND, D0−OUT, D3+OUT, D3GND, and D3−OUT which are arranged in the X-direction. The input terminals D2+IN, D2GND, D2−IN, D1+IN, D1GND, D1−IN, D0+IN, D0GND, D0−IN, D3+IN, D3GND, and D3−IN which are provided on the upper surface 151 and the output terminals D2+OUT, D2GND, D2−OUT, D1+OUT, D1GND, D1−OUT, D0+OUT, D0GND, D0−OUT, D3+OUT, D3GND, and D3−OUT which are provided on the lower surface 152 overlap each other respectively.

The circuit board 150 is an array product including four mutually independent unit circuits U0 to U3, to each of which one common mode filter 71 and one TVS chip 72 are allocated.

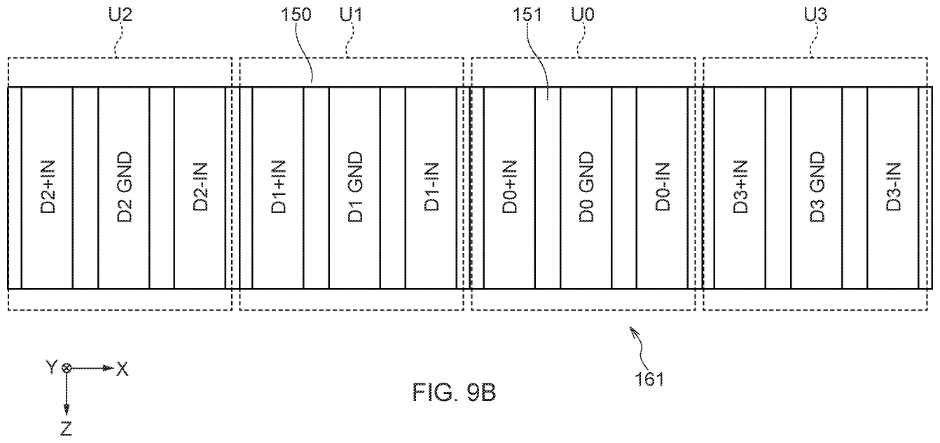

FIG. 10 is a schematic cross-sectional view for explaining the structure of the circuit board 150. As illustrated in FIG. 10, the circuit board 150 has a structure in which conductor layers L1 to L5 and interlayer insulating films 181 to 184 are alternately stacked. The interlayer insulating films 181 and 184 are each a layer having high strength which is made of a material obtained by impregnating a core material such as glass cloth with a resin material. The interlayer insulating film 181 has the conductor layer L2 embedded therein. The interlayer insulating film 182 is made of a resin material not containing a core material such as glass cloth and has the conductor layer L3 embedded therein. The conductor layers L2 and L3 partly constitute the common mode filter 71. The interlayer insulating film 183 is a core insulating layer and has the TVS chip 72 embedded therein. The interlayer insulating film 183 is also made of a resin material not containing a core material such as glass cloth. The interlayer insulating film 183 has main surfaces 183a and 183b constituting the XY plane and positioned on the mutually opposite sides. The interlayer insulating films 182 and 181 are stacked in this order on the main surface 183a of the interlayer insulating film 183, and the interlayer insulating film 184 is stacked on the main surface 183b of the interlayer insulating film 183.

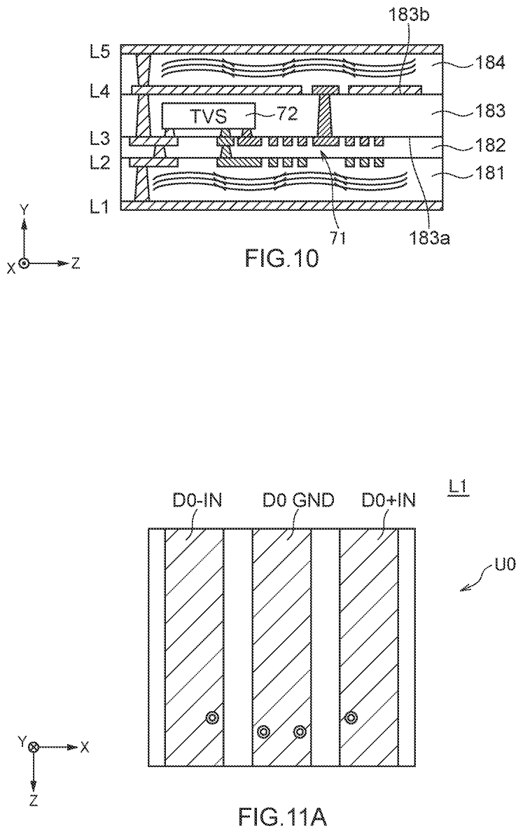

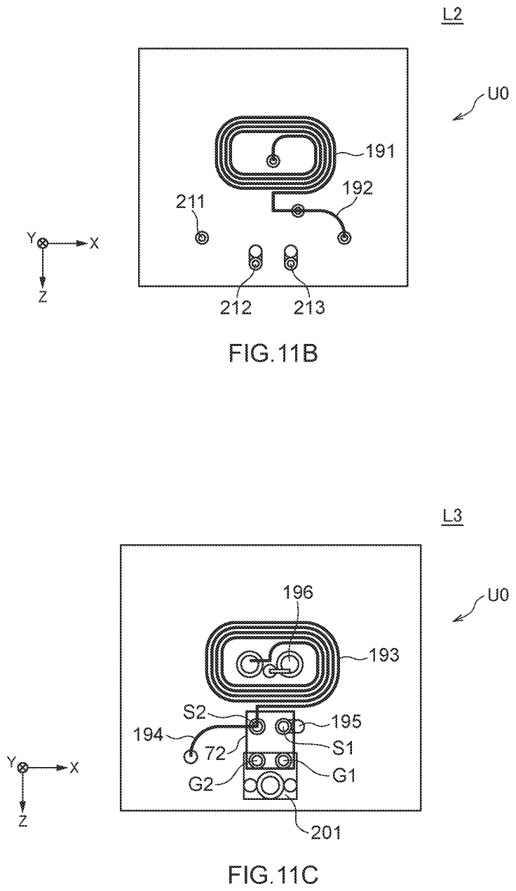

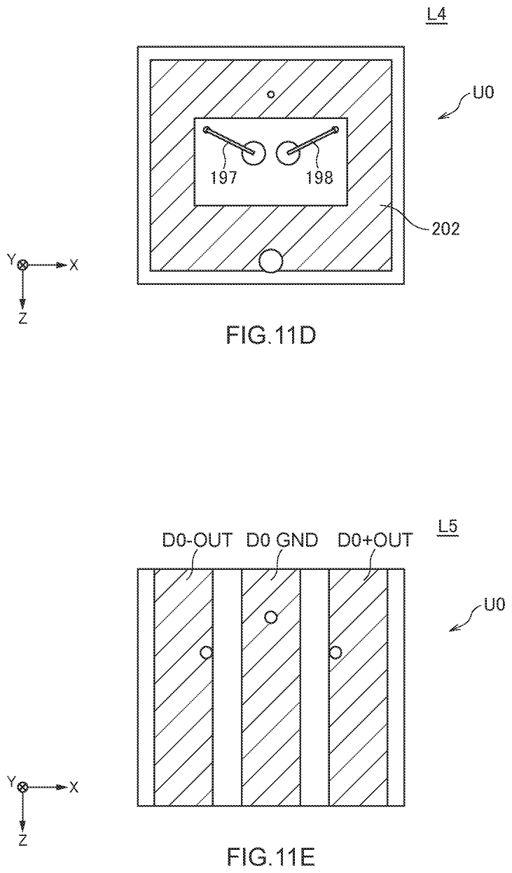

FIGS. 11A to 11E are schematic plan views respectively illustrating the structures of the conductor layers L1 to L5 and each show a portion corresponding to the unit circuit U0.

As illustrated in FIG. 11A, the conductor layer L1 includes a plurality of input terminals D0+IN, D0GND, and D0−IN which are arranged in the X-direction. The input terminals D0+IN, D0GND, and D0−IN are provided over the entire width in the Z-direction.

As illustrated in FIG. 11B, the conductor layer L2 includes a coil pattern 191 wound in a plurality of turns and a connection pattern 192 whose one end is connected to the outer peripheral end of the coil pattern 191. The other end of the connection pattern 192 is connected to the input terminal D0+IN included in the conductor layer L1 through a via penetrating the interlayer insulating film 181. The conductor layer L2 further includes connection patterns 211 to 213. The connection pattern 211 is connected to the input terminal D0−IN included in the conductor layer L1 through a via penetrating the interlayer insulating film 181. The connection patterns 212 and 213 are connected to the ground terminal D0GND included in the conductor layer L1 through a via penetrating the interlayer insulating film 181.

As illustrated in FIG. 11C, the conductor layer L3 includes a coil pattern 193 wound in a plurality of turns and a connection pattern 194 whose one end is connected to the outer peripheral end of the coil pattern 193. The other end of the connection pattern 194 is connected to the connection pattern 211 included in the conductor layer L1 through a via penetrating the interlayer insulating film 182. The coil patterns 191 and 193 overlap each other in a plan view (as viewed in the Z-direction) to constitute the common mode filter 71.

In FIG. 11C, the TVS chip 72 embedded in the interlayer insulating film 183 is illustrated. The conductor layer L3 further includes a connection pattern 195 provided outside the coil pattern 193. The connection pattern 195 is connected to the connection pattern 192 included in the conductor layer L2 through a via penetrating the interlayer insulating film 182. The connection pattern 195 is also connected to the signal terminal S1 of the TVS chip 72. The connection pattern 194 is connected to the signal terminal S2 of the TVS chip 72. The ground terminals G1 and G2 of the TVS chip 72 are connected in common to a ground pattern 201 included in the conductor layer L3. The conductor layer L3 further includes a connection pattern 196 provided in the inner diameter area of the coil pattern 193. The connection pattern 196 is connected to the inner peripheral end of the coil pattern 191 included in the conductor layer L2 through a via penetrating the interlayer insulating film 182.

As illustrated in FIG. 11D, the conductor layer L4 includes connection patterns 197 and 198 and a ground pattern 202. One end of the connection pattern 197 is connected to the inner peripheral end of the coil pattern 193 included in the conductor layer L3 through a via penetrating the interlayer insulating film 183. One end of the connection pattern 198 is connected to the connection pattern 196 included in the conductor layer L3. The ground pattern 202 has an annular structure surrounding the connection patterns 197 and 198 and is connected to the ground pattern 201 included in the conductor layer L3 through a via penetrating the interlayer insulating film 183.

As illustrated in FIG. 11E, the conductor layer L5 includes the output terminal D0+OUT, D0GND, and D0−OUT which are arranged in the X-direction. The output terminal D0+OUT is connected to the other end of the connection pattern 198 through a via penetrating the interlayer insulating film 184. The output terminal D0−OUT is connected to the other end of the connection pattern 197 through a via penetrating the interlayer insulating film 184. The ground terminal D0GND is connected to the ground pattern 202 through a via penetrating the interlayer insulating film 184. The output terminals D0+OUT, D0GND, and D0−OUT are provided over the entire width in the Z-direction.

With the above configuration, the unit circuit U0 constitutes the circuit illustrated in FIG. 7. Other unit circuits U1 to U3 have the same configuration as the unit circuit U0. Thus, the unit circuits U0 to U3 each can remove common mode noise to be superimposed on its corresponding differential signals and can remove ESD noise.

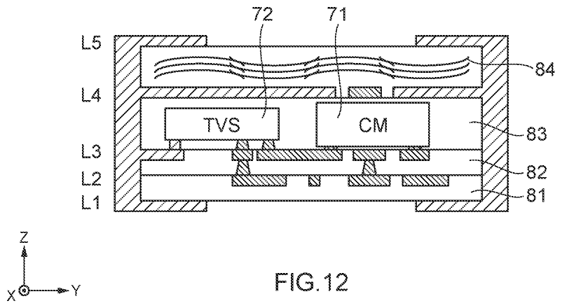

Although the TVS chip 72 is embedded in the circuit board in the above-described connector devices 10A and 10B, the type of an electronic component to be embedded in the circuit board is not particularly limited. Further, although the common mode filter 71 is formed by the conductor patterns included in the conductor layers L2 and L3 in the connector devices 10A and 10B, a chip type common mode filter (CM) may be embedded in the circuit board as illustrated in FIG. 12, for example.

While the one embodiment of the present disclosure has been described, the present disclosure is not limited to the above embodiment, and various modifications may be made within the scope of the present disclosure, and all such modifications are included in the present disclosure.

What is claimed is:

1. A circuit board comprising:
a core insulating layer including a first main surface and a second main surface opposite to each other;
an electronic component embedded in the core insulating layer and including a first inner electrode, a second inner electrode, and a third inner electrode;
a first interlayer insulating layer and a second interlayer insulating layer stacked on the first main surface of the core insulating layer;
a third interlayer insulating layer stacked on the second main surface of the core insulating layer and including a core material formed by a resin impregnated material;
a first outer electrode, a second outer electrode, a third outer electrode, a fourth outer electrode, and a fifth outer electrode;
a first coil pattern embedded in the first interlayer insulating layer and including a first end and a second end, the first end being electrically connected to the first outer electrode and the first inner electrode, and the second end being electrically connected to the second outer electrode; and
a second coil pattern embedded in the second interlayer insulating layer so as to substantially overlap the first coil pattern and including a third end and a fourth end, the third end being electrically connected to the third outer electrode and the second inner electrode, and the fourth end being electrically connected to the fourth outer electrode,
wherein the third inner electrode is connected to the fifth outer electrode, and
wherein the electronic component is arranged so as not to overlap the first coil pattern and the second coil pattern.

2. The circuit board as claimed in claim 1, wherein each of the first interlayer insulating layer and the second interlayer insulating layer includes no core material formed by a resin impregnated material.

3. The circuit board as claimed in claim 2, wherein a thickness of the third interlayer insulating layer is greater than a sum of thicknesses of the first interlayer insulating layer and the second interlayer insulating layer.

4. The circuit board as claimed in claim 1,
wherein the first interlayer insulating layer includes no core material formed by a resin impregnated material, and
wherein the second interlayer insulating layer includes a core material formed by a resin impregnated material.

5. The circuit board as claimed in claim 1,
wherein the circuit board includes a first side surface and a second side surface opposite to each other and parallel with a stacking direction,
wherein the first outer electrode and the third outer electrode are exposed on the first side surface, and
wherein the second outer electrode and the fourth outer electrode are exposed on the second side surface.

6. The circuit board as claimed in claim 5,
wherein the circuit board includes a first through hole, a second through hole, a third through hole, and a fourth through hole penetrating therethrough,
wherein the first outer electrode, the second outer electrode, the third outer electrode, and the fourth outer electrode are formed on inner surfaces of the first through hole, the second through hole, the third through hole, and the fourth through hole, respectively,
wherein the inner surfaces of the first through hole and the third through hole are exposed on the first side surface, and
wherein the inner surfaces of the second through hole and the fourth through hole are exposed on the second side surface.

7. The circuit board as claimed in claim 6, further comprising a sixth outer electrode connected to the fifth outer electrode,
wherein the circuit board includes a fifth through hole and a sixth through hole penetrating therethrough,
wherein the fifth through hole is arranged between the first through hole and the third through hole,
wherein the sixth through hole is arranged between the second through hole and the fourth through hole,
wherein the fifth outer electrode and the sixth outer electrode are formed on inner surfaces of the fifth through hole and the sixth through hole, respectively,
wherein the inner surface of the fifth through hole are exposed on the first side surface, and
wherein the inner surface of the sixth through hole are exposed on the second side surface.

8. The circuit board as claimed in claim 1,
wherein the circuit board includes a top surface and a bottom surface opposite to each other and perpendicular to a stacking direction,
wherein the first outer electrode and the third outer electrode are exposed on the top surface,
wherein the second outer electrode and the fourth outer electrode are exposed on the bottom surface,
wherein the first outer electrode and the second outer electrode substantially overlap each other, and
wherein the third outer electrode and the fourth outer electrodes substantially overlap each other.

9. The circuit board as claimed in claim 8, further comprising a sixth outer electrode connected to the fifth outer electrode,
wherein the fifth outer electrode is arranged between the first outer electrode and the third outer electrode on the top surface,
wherein the sixth outer electrode is arranged between the second outer electrode and the fourth outer electrode on the bottom surface, and
wherein the fifth outer electrode and the sixth outer electrode substantially overlap each other.

10. The circuit board as claimed in claim 1, wherein the electronic component includes a TVS chip.

11. A circuit array comprising a plurality of circuit boards,
wherein each of the circuit board is the circuit board as claimed in claim 1,
wherein each of the plurality of circuit boards is arranged side by side and integrated with each other.

12. A connector device comprising:
a receptacle;
a first lead electrode group including first lead electrode, a fifth lead electrode, and a third lead electrode arranged in this order;
a second lead electrode group including a second lead electrode, a sixth lead electrode, and a fourth lead electrode arranged in this order; and
a circuit board disposed in the receptacle;
wherein the circuit board includes:
an electronic component including a first inner electrode, a second inner electrode, a third inner electrode, and a fourth inner electrode;
a first outer electrode, a second outer electrode, a third outer electrode, and a fourth outer electrode; and
a fifth outer electrode and a sixth outer electrode connected to the third inner electrode and the fourth inner electrode, respectively;
wherein the circuit board is sandwiched between the first lead electrode group and the second lead electrode group such that:
the first outer electrode, the fifth outer electrode, and the third outer electrode are respectively connected to the first lead electrode, the fifth lead electrode, and the third lead electrode belonging to the first lead electrode group, and that
the second outer electrode, the sixth outer electrode, and the fourth outer electrode are respectively connected to the second lead electrode, the sixth lead electrode, and the fourth lead electrode belonging to the second lead electrode group.

13. The connector device as claimed in claim 12, wherein the electronic component includes a first TVS element connected between the first inner electrode and the third inner electrode and a second TVS element connected between the second inner electrode and the fourth inner electrode.

14. The connector device as claimed in claim 13, wherein the circuit board further comprises:
a first coil pattern including a first end and a second end, the first end being electrically connected to the first outer electrode and the first inner electrode, the second end being electrically connected to the second outer electrode; and
a second coil pattern substantially overlapping the first coil pattern in a first direction and including a third end and a fourth end, the third end being electrically connected to the third outer electrode and the second inner electrode, the fourth end being electrically connected to the fourth outer electrode.

15. The connector device as claimed in claim 13,
wherein the circuit board further comprises a coil chip integrating a first coil pattern and a second coil pattern,
wherein the first coil pattern is electrically connected between the first outer electrode and the second outer electrode, and
wherein the second coil pattern is electrically connected between third outer electrode the fourth outer electrode.

16. The connector device as claimed in claim 12,
wherein the circuit board includes a first side surface and a second side surface opposite to each other and parallel with the first direction,
wherein the first outer electrode, the fifth outer electrode, and the third outer electrode are exposed on the first side surface, and
wherein the second outer electrode, the sixth outer electrode, and the fourth outer electrode are exposed on the second side surface.

17. The connector device as claimed in claim 16,
wherein the circuit board includes a first through hole, a second through hole, a third through hole, a fourth through hole, a fifth through hole, and a sixth through hole penetrating therethrough,
wherein the first outer electrode, the second outer electrode, the third outer electrode, the fourth outer electrode, the fifth outer electrode, and the sixth outer electrode are formed on inner surfaces of the first through hole, the second through hole, the third through hole, the fourth through hole, the fifth through hole, and the sixth through hole, respectively,
wherein the inner surfaces of the first through hole, the fifth through hole, and the third through hole are exposed on the first side surface, and
wherein the inner surfaces of the second through hole, the sixth through hole, and the fourth through hole are exposed on the second side surface.

18. The connector device as claimed in claim 17,
wherein the first lead electrode group biases the first side surface of the circuit board such that the first lead electrode, the fifth lead electrode, and the third lead electrode are elastically contacted to the first outer electrode, the fifth outer electrode, and the third outer electrode, respectively, and
wherein the second lead electrode group biases the second side surface of the circuit board such that the second lead electrode, the sixth lead electrode, and the fourth lead electrode are elastically contacted to the second outer electrode, the sixth outer electrode, and the fourth outer electrode, respectively.

19. The connector device as claimed in claim 12,
wherein the circuit board includes a top surface and a bottom surface opposite to each other and perpendicular to the first direction,
wherein the first outer electrode, the fifth outer electrode, and the third outer electrode are exposed on the top surface,
wherein the second outer electrode, the sixth outer electrode, and the fourth outer electrode are exposed on the bottom surface,
wherein the first outer electrode and the second outer electrode substantially overlap each other,
wherein the third outer electrode and the fourth outer electrode substantially overlap each other, and
wherein the fifth outer electrode and the sixth outer electrode substantially overlap each other.

20. The connector device as claimed in claim 19,
wherein the first lead electrode group biases the top surface of the circuit board such that the first lead electrode, the fifth lead electrode, and the third lead electrode are elastically contacted to the first outer electrode, the fifth outer electrode, and the third outer electrode, respectively, and
wherein the second lead electrode group biases the bottom surface of the circuit board such that the second lead electrode, the sixth lead electrode, and the fourth lead electrode are elastically contacted to the second outer electrode, the sixth outer electrode, and the fourth outer electrode, respectively.

21. A connector device comprising:
a receptacle;
a first lead electrode group including a plurality of first sub-groups each including a first lead electrode, a fifth lead electrode, and a third lead electrode;
a second lead electrode group including a plurality of second sub-groups each including a second lead electrode, a sixth lead electrode, and a fourth lead electrode; and
a circuit board disposed in the receptacle and including a plurality of circuit units,
wherein each of the plurality of circuit units includes:
an electronic component having a first inner electrode, a second inner electrode, a third inner electrode, and a fourth inner electrode;
a first outer electrode, a second outer electrode, a third outer electrode, and a fourth outer electrode; and
a fifth outer electrode and a sixth outer electrode connected to the third inner electrode and the fourth inner electrode, respectively;
wherein the circuit board is sandwiched between the first lead electrode group and the second lead electrode group such that:
the first outer electrode, the fifth outer electrode, and the third outer electrode of each of the plurality of circuit units are connected to the first lead electrode, the fifth lead electrode, and the third lead electrode of corresponding one of the first sub-groups, and that
the second outer electrode, the sixth outer electrode, and the fourth outer electrode of each of the plurality of circuit units are connected to the second lead electrode, the sixth lead electrode, and the fourth lead electrode of corresponding one of the second sub-groups.
